(19) United States
(12) Patent Application Publication
(10) Pub. No.: US 2017/0099737 A1
(43) Pub. Date: Apr. 6, 2017

(54) DEPOSITION METHOD AND APPARATUS

(71) Applicant: V TECHNOLOGY CO., LTD., Yokohama-shi (JP)

(72) Inventors: Koichi KAJIYAMA, Yokohama-shi (JP); Michinobu MIZUMURA, Yokohama-shi (JP)

(21) Appl. No.: 15/380,957

(22) Filed: Dec. 15, 2016

Related U.S. Application Data
(63) Continuation of application No. PCT/JP2015/069287, filed on Jul. 3, 2015.

(30) Foreign Application Priority Data
Jul. 14, 2014 (JP) 2014-143972

(51) Int. Cl. H05K 3/10; B05D 1/32; B05D 1/02

(52) U.S. Cl. CPC H05K 3/108; B05D 1/02; B05D 1/32

(57) ABSTRACT

The present invention includes the steps of applying a liquid deposition material on a display surface of a display panel through a metal mask which is in close contact with the display surface of the display panel, while heating the metal mask; and forming thin film patterns by heating and baking the applied liquid deposition material.

### CROSS REFERENCE TO RELATED APPLICATION

This application is a continuation application of PCT/JP2015/069287, filed on Jul. 3, 2015.

### BACKGROUND OF THE INVENTION

1. Field of the Invention

The present invention relates to a deposition method and an apparatus for forming thin film patterns by applying a liquid deposition material on the deposition surface of a substrate through a metal mask, and then heating and baking the liquid deposition material, in particular, for improved accuracy.

2. Description of Related Art

A conventional deposition method includes the steps of: forming a metal thin wire pattern on a transparent resin substrate by printing a composition containing metal nanoparticles in a predetermined pattern; irradiating the metal thin wire pattern with middle infrared rays; and heating and baking the metal thin wire pattern by irradiating the metal thin wire pattern with flash light (see JP 2014-038749 A, for example).

However, in such a conventional deposition method, even if the printing mask is liquid repellent at least in a substrate contact surface, when the composition containing metal nanoparticles is liquid having high fluidity, the composition containing metal nanoparticles might get between the substrate and the shadow portions of the mask, which prevents thin film patterns from being properly formed.

To address such a problem, an object of the present invention is to provide a deposition method and a deposition apparatus capable of forming thin film patterns with improved accuracy.

### SUMMARY OF THE INVENTION

To achieve this object, a deposition method according to the present invention includes the steps of: applying a liquid deposition material on a deposition surface of a substrate through a metal mask which is in close contact with the deposition surface of the substrate, while heating the metal mask; and forming thin film patterns by heating and baking the applied liquid deposition material.

A deposition apparatus according to the present invention is for forming thin film patterns by applying a liquid deposition material on a deposition surface of a substrate through a metal mask, and then heating and baking the liquid deposition material, and includes: a heating device for heating the metal mask; and an application device for applying the deposition material on the deposition surface of the substrate through the metal mask while the heating device is heating the metal mask.

According to the present invention, the liquid deposition material is applied through the heated metal mask. This partially and rapidly cures the deposition material that is adhered to the metal mask or increases its viscosity, and thus prevents the liquid deposition material from flowing even under the shadow portions of the metal mask and being adhered to the substrate there. Accordingly, the shapes of the aperture patterns of the metal mask can be exactly transferred on the substrate, so that the thin film patterns can be formed with improved accuracy.

### BRIEF DESCRIPTION OF THE DRAWINGS

FIG. 1 is a schematic configuration diagram of an embodiment of a deposition apparatus according to the present invention.

FIG. 2A is a plan view of a substantial part, and FIG. 2B is a cross-sectional view taken along A-A line viewed from arrows of FIG. 2A, each of which shows an exemplary configuration of the metal mask used in the deposition apparatus.

FIG. 3 illustrates how the deposition apparatus applies a deposition material.

FIG. 4 is an enlarged cross-sectional view showing the part enclosed by circle B of FIG. 3 for illustrating problems of a conventional deposition apparatus using a metal mask.

FIGS. 5A to 5C are enlarged cross-sectional views each showing the part enclosed by circle B of FIG. 3, illustrating procedural steps of the deposition method according to the present invention.

### DESCRIPTION OF PREFERRED EMBODIMENTS

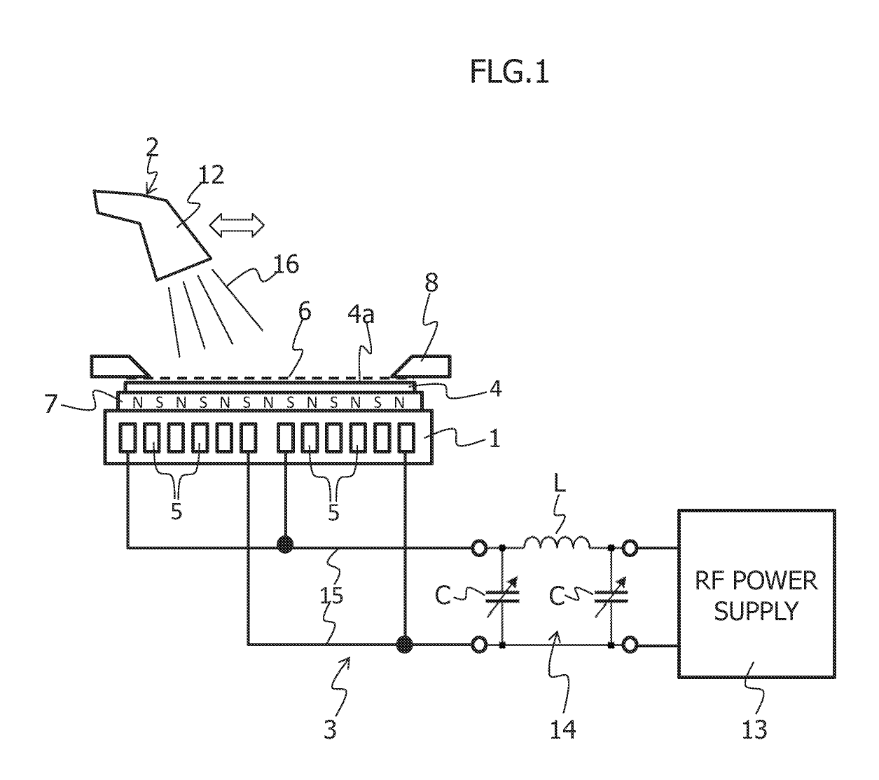

Hereinafter, an embodiment of the present invention will be described in detail with reference to the accompanying drawings. FIG. 1 is a schematic configuration diagram of an embodiment of a deposition apparatus according to the present invention. The deposition apparatus is for forming thin film patterns by applying a liquid deposition material on a deposition surface of a substrate through a metal mask and then heating and baking the deposition material, and includes a stage 1, an application device 2, a heating device 3 and baking means (not shown).

The stage 1 is provided inside the main body of the deposition apparatus. The stage 1 is to hold a substrate on which deposition is performed, such as a display panel 4, and is made of a non-metallic material. The stage 1 contains a radio-frequency (hereinafter abbreviated as “RF”) induction antenna coils 5 constituting the heating device 3 which will be described later.

A metal mask 6 made of a magnetic metallic material is fixed on a display surface 4a of the display panel 4 in close contact with the display surface 4a by attraction to a sheet magnet 7 disposed on the back surface of the display panel 4, which back surface is opposite to the display surface 4a.

The metal mask 6 has a plurality of aperture patterns 9 each having the same shape and dimensions as those of the corresponding one of the thin film patterns to be formed by deposition. For example, the metal mask 6 is a mask sheet made of a material such as nickel, a nickel alloy, invar or an invar alloy and having a thickness of approximately 10 μm to 30 μm. A metal frame 8 having a frame shape and made of a material such as invar or an invar alloy is bonded onto the peripheral edge of a surface of the mask sheet.

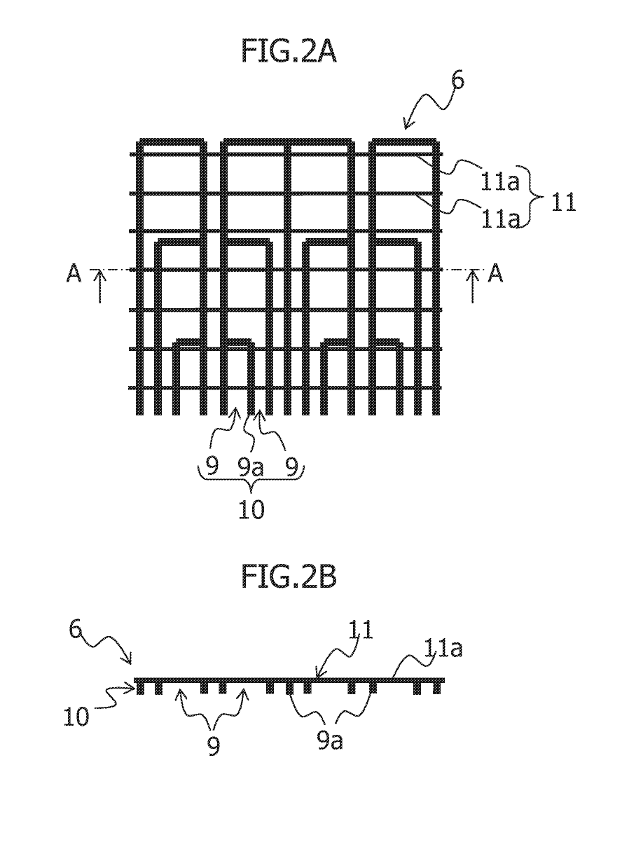

Specifically, as shown in FIGS. 2A and 2B, the metal mask 6 includes a mask layer 10 provided with the plurality of aperture patterns 9, and a support layer 11 made of a plurality of thin lines (hereinafter referred to as “support lines 11a”) provided on a surface of the mask layer 10 so as to extend across the aperture patterns 9. The mask layer 10 and the support layer 11 are formed by two-stage electroplating process. This allows the support lines 11a extending across the aperture patterns 9 to support the mask layer 10 so as to maintain the shapes of the aperture patterns 9 even when partitions (shadow portions) 9a each separating two of the aperture patterns 9 are small in width.

The application device 2 is provided above the stage 1. This application device 2 is for applying a liquid deposition material 16 on the display surface 4a of the display panel 4, and includes a spray nozzle 12 for spraying the deposition material 16. The deposition material 16 is made, for example, of carbon nanotubes (CNTs), nanoparticles of an indium tin oxide (ITO) or metal nanoparticles, dispersed in a solution. A movement mechanism (not shown) makes the spray nozzle 12 movable in a plane parallel to the top surface of the stage 1 as indicated by white arrow of FIG. 1.

To be specific, for example, the application device 2 supplies high-speed air to the distal end of the spray nozzle 12 so as to suction the deposition material 16 to the distal end of the spray nozzle 12 through a tube from a storage tank using a negative pressure created at this distal end by the Venturi effect, and to cause the deposition material 16 that is made into a mist by the high-speed air to spray out.

The stage 1 contains the RF induction antenna coils 5, and is thus provided with the heating device 3. The heating device 3 is for heating, using radio-frequency induction heating, the metal mask 6 fixed in close contact with the display panel 4 that is held on the stage 1 at a temperature lower than the baking temperature of the liquid deposition material 16. The heating device 3 includes an RF power supply 13, the RF induction antenna coils 5 and an impedance-matching circuit 14.

Specifically, the RF power supply 13 generates a radio-frequency wave from 1.5 kHz to 400 kHz, for example. Each RF induction antenna coil 5 is configured to generate an electromagnetic field around it when a radio-frequency current flows therethrough. This induction field causes an induced current to flow through the interior of the metal mask 6, and thereby generates Joule heat in the metal mask 6 to heat itself. The impedance-matching circuit 14 is for efficiently transmitting, to the RF induction antenna coils 5, radio-frequency power generated in the RF power supply 13. The impedance-matching circuit 14 is inserted in a transmission path 15 connecting the RF power supply 13 with the RF induction antenna coils 5 so as to prevent or reduce reflected waves in the transmission path 15, and thus allow the heating device 3 to provide the maximum output. The impedance-matching circuit 14 is a commonly used matching device in which a coil L and capacitors C are combined.

The baking means (not shown) is provided inside the main body of the deposition apparatus. The baking means is for heating, baking and curing the liquid deposition material 16 applied on the display panel 4, and may be, for example, resistive heating means. The baking means may be contained in the stage 1 or in a second stage provided separately from the stage 1. When the baking means is provided in the second stage, the deposition apparatus should preferably be configured to cause a conveying mechanism (not shown) to transport, from the stage 1 to the second stage, the display panel 4 on which the deposition material 16 is applied.

Next, the operation of the deposition apparatus configured as above and the deposition method will be described.

First, as shown in FIG. 1, the metal mask 6 becomes fixed in close contact with the display surface 4a of the display panel 4 by attraction to the sheet magnet 7 disposed on the back surface of the display panel 4.

Specifically, under the condition where the sheet magnet 7 is disposed on the back surface of the display panel 4, the metal mask 6 is placed above the display panel 4 with the mask layer 10 facing the display panel 4 so that the metal mask 6 can be spaced therefrom by a small distance within a range that allows no or little magnetic force of the magnet 7 to affect the metal mask 6. Under these conditions, the metal mask 6 becomes aligned with the display panel 4 using, for example, alignment references previously provided to the display panel 4 and the metal mask 6. When the metal mask 6 is successfully aligned with the display panel 4, the metal mask 6 is moved down and placed on the display panel 4. In this event, the metal mask 6 is attracted toward the display panel 4 by a magnetic force of the magnet 7 disposed on the back surface of the display panel 4. As a result, the metal mask 6 becomes fixed in close contact with the display surface 4a of the display panel 4.

The display panel 4 on which the metal mask 6 is fixed in close contact therewith is placed on the stage 1 inside the main body of the deposition apparatus. Note that the above sequence of steps may alternatively be performed with the display panel 4 placed on the stage 1.

Next, the RF power supply 13 of the heating device 3 is activated, so that a radio-frequency current becomes supplied to the RF induction antenna coils 5. In this event, the capacitance of each capacitor C in the impedance-matching circuit 14 is controlled so as to minimize reflected waves in the transmission path 15.

When the radio-frequency current supplied from the RF power supply 13 flows through the RF induction antenna coils 5, an electromagnetic field is generated around each RF induction antenna coil 5. This electromagnetic field causes an induced current to flow through the interior of the metal mask 6. The induced current flowing through the interior of the metal mask 6 generates Joule heat in the metal mask 6 to heat itself. The amount of heat generated by the metal mask 6 can be controlled by the amount of power supplied from the RF power supply 13 to the RF induction antenna coils 5. In this embodiment, the heat generation of the metal mask 6 is controlled so that the temperature of the metal mask 6 is lower than the baking temperature (curing temperature: 130° C.) of the liquid deposition material 16 employed, such as carbon nanotubes. Here, the display panel 4, which is made of a non-metallic material, is not heated by the radio-frequency electromagnetic field. Thus, substantially only the metal mask 6 is heated by induction.

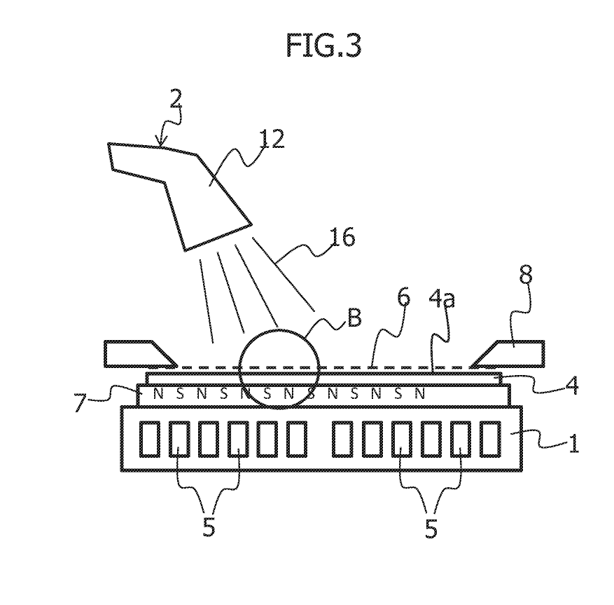

When the temperature of the metal mask 6 reaches a preset temperature, the liquid deposition material 16 is sprayed out to the display panel 4 from the spray nozzle 12, as shown in FIG. 3. Thereby, the deposition material 16 is applied on the display surface 4a of the display panel 4 in regions corresponding to the aperture patterns 9 provided in the mask layer 10 of the metal mask 6 to a preset thickness, for example, of approximately several hundreds nm to several Specifically, the deposition material 16 is sprayed from the spray nozzle 12 while the spray nozzle 12 is moved, for example, forwards and backwards or in a zigzag pattern, in a plane parallel to the display surface 4a of the display panel 4.

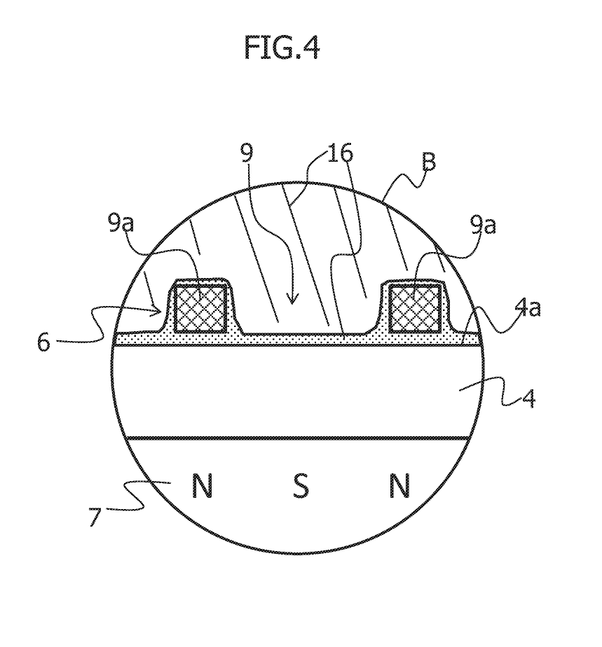

Here, even though the metal mask 6 is in close contact with the display surface 4a of the display panel 4 by attraction to the magnet 7, a slight gap remains between the metal mask 6 and the display panel 4. Accordingly, if the deposition material 16 is applied before the metal mask 6 is heated, the applied liquid deposition material 16 gets even under the partitions 9a between adjacent ones of the aperture patterns 9 in the metal mask 6 as shown in FIG. 4 since the fluidity of the deposition material 16 is high under such a condition. This reduces the shape accuracy of the resultant thin film patterns, which is problematic. In particular, when the partitions 9a are small in width, the deposition material 16 applied into any adjacent ones of the aperture patterns 9 might join together under the partitions 9a.

To address the above problem, in the present invention, the deposition material 16 is applied through the heated metal mask 6. This will be described in detail hereinafter.

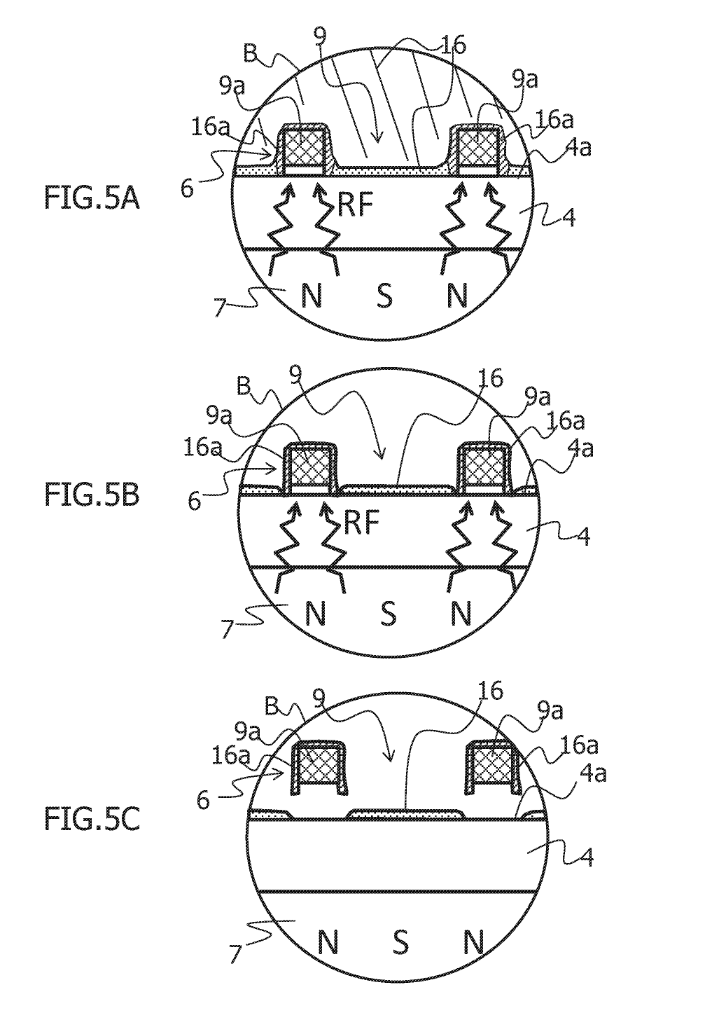

FIGS. 5A to 5C are enlarged cross-sectional views each showing the part enclosed by circle B of FIG. 3, illustrating the deposition method according to the present invention.

First, as shown in FIG. 5A, the deposition material 16 is sprayed through the metal mask 6 that is heated by induction. Thereby, the deposition material 16 is adhered onto the metal mask 6 and the regions, corresponding to the aperture patterns 9 of the metal mask 6, of the display surface 4a of the display panel 4.

In this event, since the metal mask 6 is heated, the deposition material 16a adhered to the metal mask 6 is partially cured or increases in viscosity as indicated by shaded area of FIG. 5A. This deposition material 16a partially cured or increased in viscosity serves as a barrier to prevent the deposition material 16 from getting under the partitions 9a between adjacent ones of the aperture patterns 9 in the metal mask 6.

As shown in FIG. 5B, the metal mask 6 is kept heated by induction till the completion of the application of the deposition material 16. Upon the completion of the application of the deposition material 16, the metal mask 6 is peeled off the display panel 4 as shown in FIG. 5C. In this event, since the deposition material 16a adhered to the metal mask 6 is partially cured or having a high viscosity, the deposition material 16a adhered to the metal mask 6 is easily separated from the uncured deposition material 16 adhered to the display surface 4a of the display panel 4. As a result, the shapes of the aperture patterns 9 of the metal mask 6 are accurately transferred, so that the deposition material 16 left on the display surface 4a of the display panel 4 has the shapes of the target thin film patterns.

The deposition material 16 adhered to the display panel 4 is heat-baked by the baking means provided inside the main body of the deposition apparatus. Specifically, when the resistive heating means is provided as an example of the baking means and contained in the stage 1, power supply to the resistive heating means is started after the metal mask 6 is peeled off the display surface 4a of the display panel 4, and the display panel 4 is heated at, for example, 130° C., which is a baking temperature of carbon nanotubes. Thereby, the carbon nanotubes, an example of the deposition material 16, that are adhered to the display panel 4 are cured to form the carbon-nanotube thin film patterns.

Alternatively, when the baking means is contained in the second stage, which is provided separately from the stage 1, the conveying mechanism (not shown), for example, transports, from the stage 1 to the second stage, the display panel 4 on which the deposition material 16 is applied. After that, the display panel 4 is heated and the deposition material 16 is heat-baked and cured similarly to the above.

When the deposition material 16 is liquid containing, for example, carbon nanotubes (CNTs), nanoparticles of an indium tin oxide (ITO) or metal nanoparticles, the resultant thin film patterns are transparent and conductive. Thus, the manufacturing method of the present invention makes it possible also to produce a touch panel including transparent electrodes in the display panel 4 by simple processes.

Note that, though the metal mask 6 is made of a magnetic metallic material in the above embodiment, the present invention is not limited thereto. The metal mask 6 may be made of a non-magnetic metallic material. In this case, it is not necessary to dispose the magnet 7 on the back surface of the display panel 4.

Note also that, though transparent electrodes for a touch panel are formed in the above embodiment, the present invention is not limited thereto. The present invention may be applied to any method of forming thin film patterns by applying the liquid deposition material 16 on a deposition surface of a substrate through the metal mask 6, and thus may be applied to forming circuit wiring, for example.

It should be noted that the entire contents of Japanese Patent Application No. 2014-143972, filed on Jul. 14, 2014, based on which convention priority is claimed herein, is incorporated herein by reference.

It should also be understood that many modifications and variations of the described embodiments of the invention will be apparent to a person having an ordinary skill in the art without departing from the spirit and scope of the present invention as claimed in the appended claims.

What is claimed is:

1. A deposition method comprising the steps of:
applying a liquid deposition material on a deposition surface of a substrate through a metal mask which is in close contact with the deposition surface of the substrate, while heating the metal mask; and
forming thin film patterns by heating and baking the applied liquid deposition material.

2. The deposition method according to claim 1, a heating temperature of the metal mask is set lower than a baking temperature of the liquid deposition material.

3. The deposition method according to claim 1, wherein the metal mask is heated by radio-frequency induction heating.

4. The deposition method according to claim 1, wherein the metal mask is made of a magnetic metallic material so as to be in close contact with the deposition surface by attraction to a magnet disposed on an opposite side to a deposition surface side of the substrate.

5. The deposition method according to claim 1, wherein
the metal mask includes a mask layer provided with aperture patterns each having the same shape and dimensions as those of the corresponding one of the thin film patterns, and a support layer having a plurality of thin lines provided on a surface of the mask layer so as to extend across the aperture patterns, and
the metal mask is used with the mask layer in close contact with the deposition surface of the substrate.

6. The deposition method according to claim 1, wherein the liquid deposition material is made of carbon nanotubes, nanoparticles of an indium tin oxide or metal nanoparticles, dispersed in a solution.

7. A deposition apparatus for forming thin film patterns by applying a liquid deposition material on a deposition surface of a substrate through a metal mask, and then heating and baking the liquid deposition material, the deposition apparatus comprising:
a heating device for heating the metal mask; and
an application device for applying the deposition material on the deposition surface of the substrate through the metal mask while the heating device is heating the metal mask.

8. The deposition apparatus according to claim 7, the heating device uses a radio-frequency induction heating.

9. The deposition apparatus according to claim 8, wherein the radio-frequency induction heating device includes a radio-frequency induction antenna coil contained in a stage for holding the substrate.

10. The deposition apparatus according to claim 7, wherein the metal mask is made of a magnetic metallic material so as to be in close contact with the deposition surface by attraction to a magnet disposed on an opposite side to a deposition surface side of the substrate.

11. The deposition apparatus according to claim 7, wherein
the metal mask includes a mask layer provided with aperture patterns each having the same shape and dimensions as those of the corresponding one of the thin film patterns, and a support layer having a plurality of thin lines provided on a surface of the mask layer so as to extend across the aperture patterns, and
the metal mask is used with the mask layer in close contact with the deposition surface of the substrate.

12. The deposition apparatus according to claim 7, wherein the liquid deposition material is made of carbon nanotubes, nanoparticles of an indium tin oxide or metal nanoparticles, dispersed in a solution.
